(19) United States
(12) Patent Application Publication
(10) Pub. No.: US 2007/0102111 A1
(43) Pub. Date: May 10, 2007

(54) Controlled nanotube fabrication and uses

(75) Inventors: Douwe Johannes Monsma, Cambridge, MA (US); Charles Masamed Marcus, Winchester, MA (US)

Correspondence Address: WOLF GREENFIELD & SACKS, PC, FEDERAL RESERVE PLAZA, 600 ATLANTIC AVENUE, BOSTON, MA, 02210-2206, US

(73) Assignee: President and Fellows of Harvard College, Cambridge, MA (US)

(21) Appl. No.: 11/355,795

(22) Filed: Feb. 16, 2006

Related U.S. Application Data
(63) Continuation of application No. PCT/US04/25878, filed on Aug. 6, 2004.
(60) Provisional application No. 60/496,078, filed on Aug. 18, 2003.

(51) Int. Cl. B29C 65/00

(52) U.S. Cl. 156/296; 977/842

(57) ABSTRACT

A method and apparatus are provided for the formation of nanotubes and nanotube related structures. Nanotubes, such as carbon nanotubes, can be prepared to exhibit various physical, chemical and electrical properties.

### RELATED APPLICATIONS

This application is a continuation of International Patent Application Serial No. PCT/US2004/125878, filed Aug. 6, 2004, which claims priority to U.S. Provisional Patent Application Ser. No. 60/496,078, filed Aug. 18, 2003.

### FIELD OF THE INVENTION

The present invention relates generally to nanostructures, and more particularly to nanotubes and techniques for making and using the same.

### BACKGROUND OF THE INVENTION

The field of nanotechnology has produced interesting and useful particles, wires, tubes, and the like. Nanoscale circuits have been reported, as well as sensors, transistors, and other devices.

Nanotubes are generally tubular structures comprises of carbon in graphite-like arrangement, also referred to as a graphene sheet in a tubular configuration. A variety of uses of nanotubes in circuits and the like have been reported, for example as described in an International Patent Publication of Lieber, et al., No. WO 01/03208, published Jan. 11, 2001, entitled Nanoscopic Wire-Based Devices, Arrays, and Methods of Their Manufacture.

Despite advances, typical current approaches to nanotube preparation is not generally not as amenable to the fabrication of integrated circuits and other devices as would be ideal. Contacting a single nanotube with another portion(s) of a circuit can be challenging.

### SUMMARY OF THE INVENTION

In one aspect, a method is provided, the method comprising providing at least first and second separate, non-nanotube nanocomponents, and joining the at least first and second nanocomponents to form a nanotube.

In another aspect, a method is provided that comprises forming a first molecular layer and a second molecular layer, both on a branched pattern on a substrate, and joining the first and second layers to form a branched nanotube structure wherein the branched pattern directs the shape of the nanotube structure.

In another aspect, a method of forming a branched nanotube structure is provided, the method comprising providing a first substantially planar branched molecular structure, and annealing the molecular structure to a second substantially planar branched molecular structure to produce the branched nanotube structure.

In another aspect, a nanotube is provided, the nanotube comprising a first substantially cylindrical portion exhibiting a first molecular structure and a first electrical characteristic, and a second substantially cylindrical portion exhibiting the first molecular structure and a second electrical characteristic, wherein each of the first and second portions comprises at least two carbon rings.

In another aspect, a method of making a nanotube is provided, the method comprising forming a first molecular layer and a second molecular layer, each in substantially the same shape, and molecularly annealing the first layer to the second layer to produce the nanotube.

In another aspect, a method of making a nanotube is provided, the method comprising forming a molecular layer having at least first and second elongated portions, the first portion having a first orientation on a crystal lattice substrate and the second portion having a second orientation on the crystal lattice substrate wherein the first orientation is different from the second orientation, and forming a nanotube from the molecular layer wherein the nanotube includes a first portion having a first chirality and a second portion having a second chirality.

In another aspect, a method is provided, the method comprising imprinting a crystal lattice pattern onto a substrate, epitaxially forming a molecular layer on the pattern, and removing the molecular layer from the pattern.

In another aspect, a circuit is provided, the circuit comprising a pattern of nanotubes comprising a first portion having a first longitudinal orientation and a first conductance and a second portion molecularly joined to the first portion and having a second longitudinal orientation different from the first orientation and a second conductance different from the first conductance.

In another aspect, a method of making a circuit is provided, the method comprising forming a pattern on a substrate, producing a crystalline molecular layer on the pattern without producing a substantial amount of molecular layer on non-patterned portions of the substrate, and forming a circuit from the molecular layer wherein the conductivity of a portion of the circuit is determined by a horizontal dimension of the portion.

In another aspect, a method of making a circuit is provided, the method comprising forming a pattern on a substrate, depositing a crystalline molecular layer on the pattern without depositing a substantial amount of molecular layer on non-patterned portions of the substrate, and forming a circuit from the molecular layer wherein the conductivity of a portion of the circuit is determined by an orientation of the portion in relation to the crystal lattice structure of the substrate.

The subject matter of this application may involve, in some cases, interrelated products, alternative solutions to a particular problem, and/or a plurality of different uses of a single system or article.

Other advantages, features, and uses of the invention will become apparent from the following detailed description of non-limiting embodiments of the invention when considered in conjunction with the accompanying drawings, which are schematic and which are not intended to be drawn to scale. In the figures, each identical or nearly identical component that is illustrated in various figures typically is represented by a single numeral. For purposes of clarity, not every component is labeled in every figure, nor is every component of each embodiment of the invention shown where illustration is not necessary to allow those of ordinary skill in the art to understand the invention. In cases where the present specification and a document incorporated by reference include conflicting disclosure, the present specification shall control.

### BRIEF DESCRIPTION OF THE DRAWINGS

FIG. 1A provides a schematic illustration of a portion of a carbon nanotube;

FIG. 1B provides a schematic illustration of a closed fullerene tube;

FIG. 1C is a photo copy of a high resolution scanning tunneling microscope (HR-STM) image showing the helical lattice of a SWNT;

FIG. 1D provides a indexing scheme that shows the folding procedure to create nanotube cylinders from planar graphene sheets.

FIGS. 2A-2D provide a schematic structure of single wall nanotubes and how the structure determines the electronic properties of the nanotubes;

FIG. 2A (10,10) represents an arm-chair nanotube (metallic) configuration. In the lower panel, the hexagon represents the first Brillouin zone of a graphene sheet in reciprocal space. The vertical lines represent the electronic states of the nanotube. The center-line crosses two corners of the hexagon, resulting in a metallic nanotube;

FIG. 2B illustrates a zigzag nanotube(12,0). The electronic states cross the hexagon corners, but a small bandgap can develop due to the curvature of the nanotube;

FIG. 2C illustrates the zigzag tube (14,0) as semiconducting because the states on the vertical lines miss the corner points of the hexagon;

FIG. 2D illustrates a tube (7,16) that is semiconducting. This figure illustrates the extreme sensitivity of nanotube electronic structures to the diameter and chirality of nanotubes.

FIG. 3 provides a graphical illustration of bandgap as a function of carbon nanotube radius using the first principles local density functional method.

FIG. 4 provides a process flow chart of one method of nanotube integrated circuit fabrication.

FIG. 5 is a photocopy of a micrograph of TiC epitaxially sputtered onto MgO;

FIGS. 6A and 6B are photocopies of cross sectional SEM images of etched silicon features patterned by scanning probe lithography. (a) 50 nm line written in SAL601 resist and etched 300 nm into silicon and (b) 26 nm line written in PMMA, lifted off Chrome stripe and etched the silicon anisotropically.

FIG. 7A is a photocopy of an AFM image of a series of 2 nm tall, 10 nm wide, 100 nm spaced silicon oxide lines (light) fabricated by a nanotube tip;

FIG. 7B is a photocopy of silicon oxide words written by the nanotube tip of FIG. 7a;

FIG. 8A illustrates schematically how in ordinary epitaxial growth, dangling bonds create stress centers for epitaxy and defects in the grown film;

FIG. 8B illustrates schematically how in the case of VDWE, the substrate surface atoms are terminated or passivated and layered compounds can grow epitaxially across a van der Waals gap, even on lattice mismatched systems;

FIG. 9 illustrates in perspective schematically carbon nanoribbons CVD grown at 1100 K on (111) terraces of miscut TiC (755);

FIG. 10 shows graphically the energy gap of GaSe nanotube calculated within the tight bonding approach. The solid circles correspond to tight binding energy gaps where the tight binding parameters have been fit to the experimental value of the bulk. The parameter n refers to the number of GaSe unit cells around the circumference of the tube (see also FIG. 1D);

FIG. 11 is a photocopy of a TEM micrograph of graphite edge structures;

FIG. 12 simulation of multiple layer folding with a single layer involved in the arch formation. The system modeled mimics the graphite edge structure in respect to the existence of the multiple layers and the sleeves formed at the open surface.

FIG. 13 illustrates schematically the formation of a T-junction nanotube from two concentric graphene layers. Nanotube T-junction before (left) and after edge fusing (right). Depending on the angle of the TiC patterns with the crystal, the tubes on either side of the junction can be metallic, semiconducting or semiconducting and metallic, for example forming Schottky transistors.

FIGS. 14A and 14B illustrate schematically how electronic components can be formed from concentric layers of graphene. FIG. 14A shows a nanotube side gate. FIG. 14B shows a floating gate junction. These structures can edge-fuse into an insulating gate transistor and floating gate memory transistor, respectively. The floating gate may form a buckyball (buckminsterfullerene) like shape and store electrons by injection from the gate electrode. The arms of the junctions can independently be chosen to be semiconducting and or metallic.

FIG. 15 outlines a process diagram to create small pitch wires: (A) A GaAs/AlGaAs superlattice. (B) after selectively etching the AlGaAs (C) metal deposition while tilted at 36° (D) contact of superlattice onto adhesive layer on silicon (E) release of metal wires by etching GaAs oxide and (F) after optional O₂ plasma to remove adhesive layer; and

FIG. 16 Aligned Pt nanowire array using the SNAP process as outlined in FIG. 15, 8 run wide and 16 nm pitch.

### DETAILED DESCRIPTION OF THE INVENTION

As used herein, “nanoscopic-scale,” “nanoscopic,” “nanometer-scale,” “nanoscale,” the “nano-” prefix (for example, as in “nanostructured”), and the like generally refers to elements or articles having widths or diameters of less than about 1 micron, and less than about 100 nm in some cases. In all embodiments, specified widths can be a smallest width (i.e. a width as specified where, at that location, the article can have a larger width in a different dimension), or a largest width (i.e. where, at that location, the article has a width that is no wider than as specified, but can have a length that is greater).

The present invention relates to nanotubes. Traditionally, nanotubes, and carbon nanotubes in particular, have been formed by growing the tubes out of a substrate, in a direction normal to the plane of the substrate. In contrast, one aspect of the invention involves forming nanotubes in a planar form by starting with two or more planar portions of graphene, often with one layered directly on top of the other. The two planar portions can be annealed together to form a single piece, such as a nanotube. The resulting nanotube or nanotubes can be in different shapes that can be, for instance, circuits. A desired circuit can be laid out on a substrate prior to depositing the graphene, allowing numerous types of nanotube circuits to be made: Furthermore, the graphene layers can be deposited in a manner that is predictive of electrical properties, e.g., the conductivity, of the resulting nanotube. In one set of embodiments, a multi-component layer can be converted to graphene by evaporating non-carbon components from the layer to leave a graphene layer in place.

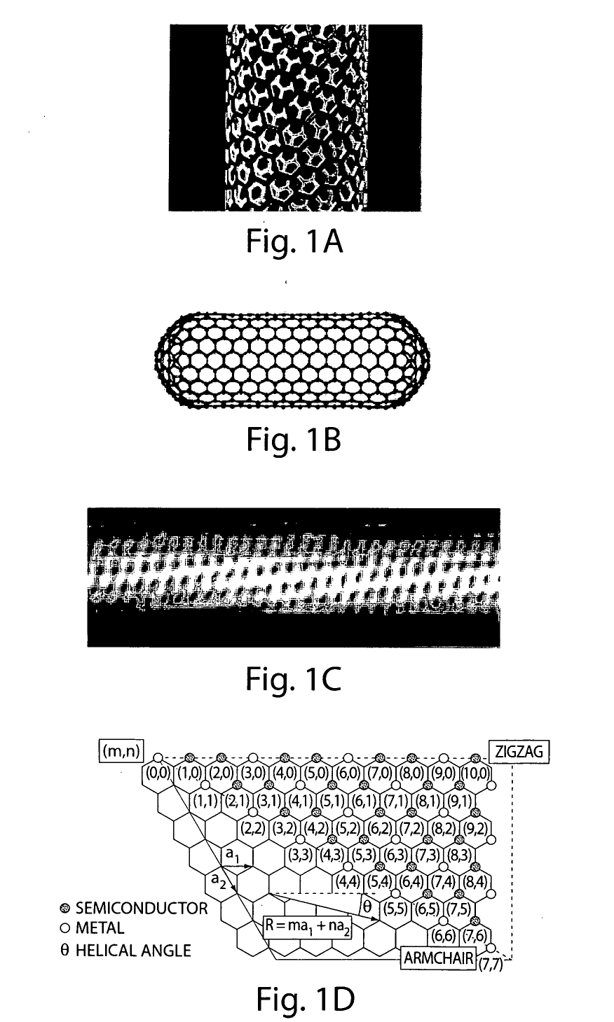

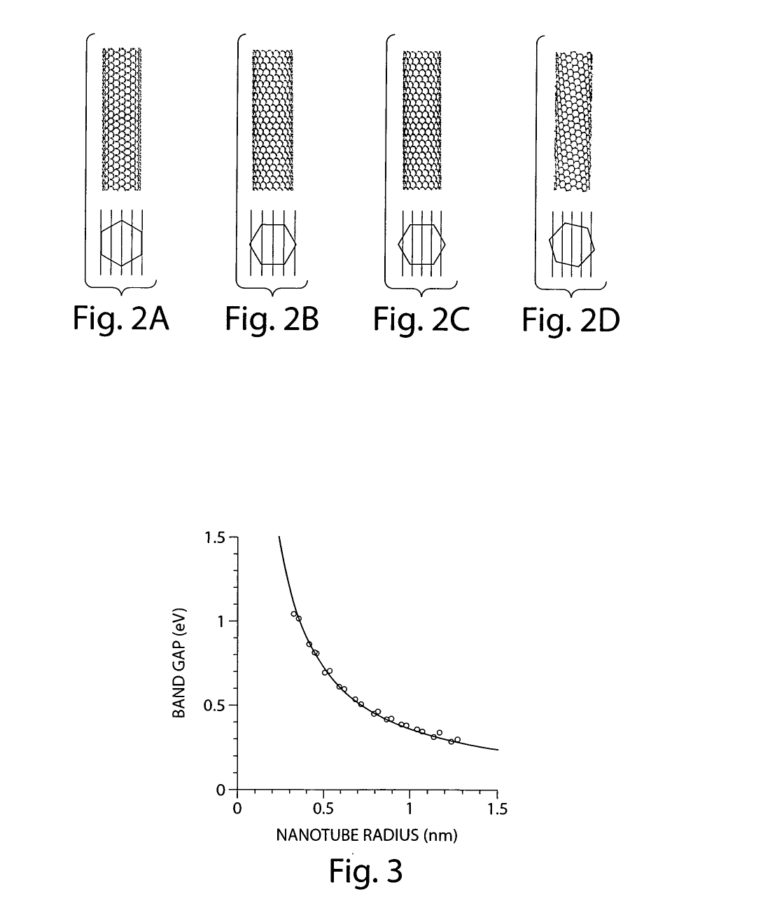

A single walled nanotube (SWNT) is a graphite-like structure in tubular form, and can be described as a rolled graphene sheet defining a monolayer of graphite. For illustration, FIG. 1 provides various views of single walled nanotubes. Other morphologies are also possible, including multi-walled nanotubes. Depending on the “rolling vector” (relationship between the axis of the nanotube and the circumferential directionality of the graphite repeat units), a nanotube can assume various structures, including different chiral structures. A nanotube can take, for example, a generally armchair, zigzag or helical configuration. FIG. 1B illustrates an armchair nanotube, and FIGS. 1A and 1C illustrate helical tubes. Armchair nanotubes are metallic, whereas zigzag and helical nanotubes generally can be metallic or semiconducting, depending, e.g. on the diameter of the tube. In FIG. 2 the semiconducting and metallic properties of various nanotube chiralities are indicated.

The bandgap of a nanotube is typically inversely proportional to the diameter of the tube, and varies from 0.1 eV to 0.6eV, when the diameter varies from 10 nm to 1 nm. As illustrated in FIG. 3, as the diameter increases, the bandgap tends to zero, yielding a zero gap semiconductor electronically equivalent to a planar graphene sheet.

SWNTs are usually produced by either arc discharge or laser ablation of a carbon target. Local growth of the tubes can also be obtained using chemical vapor deposition (CVD). In all these cases, growth is typically catalyzed by metallic particles, usually Fe, Ni or Co. These catalysts can be deposited and patterned to control the nucleation position of the nanotubes. The growth process involves heating the catalyst to high temperatures (500-1000C.) in a tube furnace, and flowing a hydrocarbon gas through the tube reactor over a period of time. The general tube formation mechanism involves the dissociation of hydrocarbon molecules catalyzed by the transition metal, and dissolution and saturation of carbon atoms in the metal nanoparticle. The precipitation from the saturated metal particle leads to the formation of tubular carbon solids in an sp² structure.

Tubule formation may be favored over other forms of graphite such as graphitic sheets with open edges because a tube has no dangling bonds and is of a lower energy form. Iron, nickel or cobalt particles are often used as catalysts. The rationale for choosing these metals as catalysts for CVD growth of nanotubes lies in the phase diagrams for these metals and carbon. At high temperatures, carbon has finite solubility in these metals, that leads to the formation of metal-carbon solid state solutions and therefore to the aforementioned growth mechanism. Direction of growth is usually vertical and flow of the gases in the CVD reactor can, to some extent, prescribe the lateral tube orientation. Catalyst free nanotubes can be obtained using vacuum annealing of silicon carbide substrates. In the latter case, nucleation starts at step edges on the substrate surface.

The present invention, in one aspect, relates generally to techniques for making nanotubes. As used herein, “nanotube” is given its ordinary meaning in the art, and generally means carbon nanotubes which can consist of essentially pure carbon in the form of a tube of what would be planar graphite if flat, and can be doped with other elements and/or carry sidegroups. Nanotubes can take a variety of forms including single-walled nanotubes (SWNT) or multi-walled nanotubes (MWNT). Typically, SWNTs of the invention are formed of a single graphene sheet rolled into a tube with a diameter on the order of 0.5 nm - 5 nm and a length that can vary, and can exceed 10 microns. Other examples of materials from which nanotubes can be made are described more fully below.

The invention, as it relates to formation of nanotubes, generally involves providing at least two nanocomponents, neither of which by itself defines a nanotube, and forming a nanotube from these two (or more) components. “Nanocomponent,” as used herein, means any structure defining at least two atoms, more typically an atomic structure which can be ordered and which has a mass of at least that of benzene, and typically of greater mass. Non-nanotube nanocomponents of the invention, from which nanotubes are formed, most typically include an ordered atomic array which, when joined to at least one other nanocomponent is essentially unchanged (except with respect to locations at which it is joined to another nanocomponent) and in this essentially unchanged formed defines a portion of a nanotube. For example, a nanocomponent may be in the shape of a ribbon and may have a width of, e.g., one, two, three, four, five or more carbon rings.

In one embodiment, a plurality of non-nanotube nanocomponents, at least some of which define an essentially planar atomic array having a thickness on the order of the diameter of the atoms defining the array (or slightly thicker where the atoms in the array do not fall in a single plane, or where side groups are bonded to the essentially planar array, or where the atomic array is non-homogeneous and includes a plurality of different kinds of atoms) are deposited on a substrate, optionally via self-assembly. Once or more of the nanocomponents can be an essentially planar array of a single type of atom each chemically bonded to another of its same kind, optionally with other atoms that fill valence vacancies in the atoms defining the planar array. In one set of embodiments, the nanocomponents are individual sheets of graphite (graphene). Much of the following description is given in the context of joining graphene sheets to form nanotubes, but it is to be understood that other nanocomponents can be used. As noted, in the description that follows a variety of optional components for nanotube fabrication are described.

Structurally, SWNTs are typically defined by a single graphene sheet in the form of a seamless tube. Depending upon diameter and helicity, SWNTs can have different electronic properties. For example, they can behave as metals or semiconductors. Generally, chirality and diameter can affect electronic properties. Chirality of conventionally formed SWNTs generally cannot be predicted and usually two-thirds are semiconducting and one third metallic. The diameter cannot easily be controlled, but is usually 1-2 nm in diameter.

Carbon nanotubes can be ideal building blocks for electronic circuits, both for conventional and quantum electronic architectures. Conventional electronics can benefit from the ultra small dimensions permitting extremely high integration and the possibility to make metallic and semiconducting components in the same material. The associated RC time delays in the circuits can be small due to the low resistance of the tubes (ballistic transport has been observed over hundreds of nanometers and micrometer coherence length is predicted for larger diameter nanotubes) and small intertube capacitance. Electron wave nature in these tubes can be controlled because of their mode quantization allowing quantum electronic circuits to be designed.

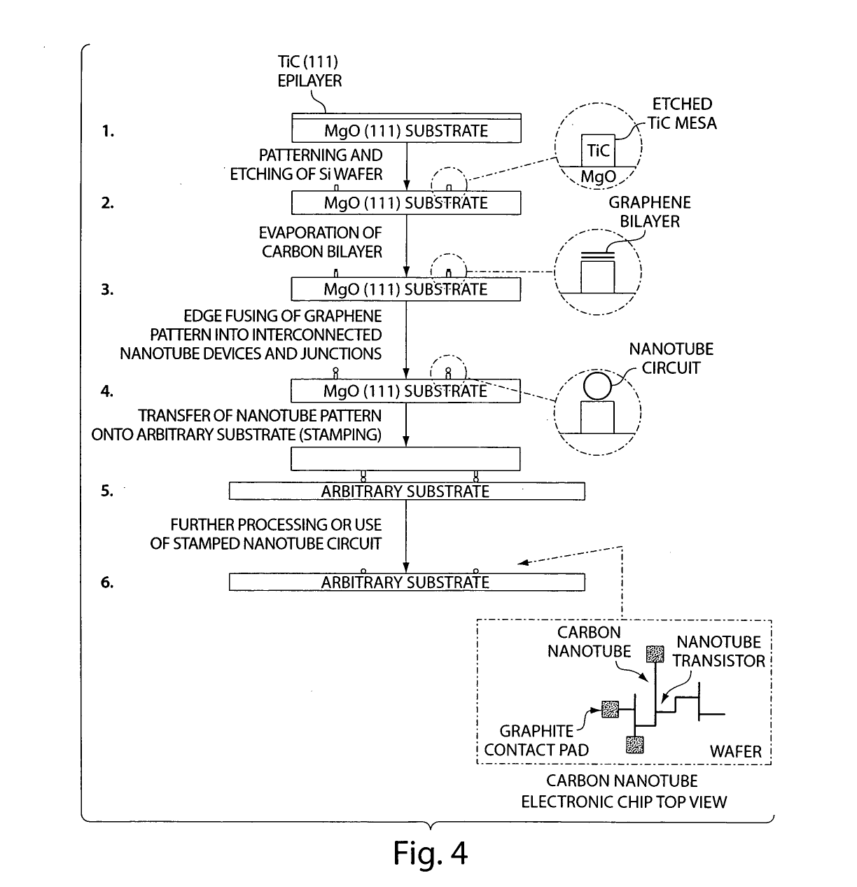

The schematic illustration of FIG. 4 and the accompanying description herein demonstrates formation of electronic circuits from nanotubes. A specific technique for forming nanotubes outlined within the schematic illustration is described more fully below. The various steps of one embodiment are illustrated below, and are examined in more detail in the next section.

Step 1: A substrate for nanocomponent deposition is formed, specifically, monolayer TiC film is epitaxially grown onto a single crystal MgO substrate.

Step 2: The TiC epilayer film is etched into mesas on the substrate having a width of 15 nm. This master substrate needs to be made only once and can thus be patterned using a slow, accurate lithographic process (E-beam, SPM lithography).

Step 3: Using chemical vapor deposition (CVD), two non-nanotube nanocomponents, specifically; molecular monolayers of carbon are deposited onto the substrate, forming van-der-Waals bonded hexagonal graphene layers (“Van-der-Waals Epitaxy”). One layer may be deposited on top of a first layer. Because the MgO substrate is inert, nano ribbons of graphene selectively form on the TiC and the graphene ribbon edges will be unterminated.

Step 4: These unterminated graphene edges will readily bond from top graphene edge to bottom edge and a nanotube will form to minimize edge strain. The local width of the mesas determines the diameter of the tubes, the local angle of the mesa stripe with respect to the substrate flat (crystal axis) determines the chirality. Thus, semiconducting and metallic tubes can be formed and on connected mesas, their junctions will form (e.g. T and Y). Depending upon the shape of the substrate, a series of interconnected nanotubes defining an electronic circuit can be formed.

Step 5: Since the nanotube circuit is only weakly (Van-der-Waals) bonded to the substrate, it can be removed from the substrate and transferred to an unpatterned arbitrary second substrate. This second substrate may have an activated surface to provide adherence and facilitate transfer (nanoimprinting/stamping) from the master.

Step 6: After formation of the first layer circuit, a second layer can be transferred from another master substrate, for example after depositing an insulating layer on top of the first circuit. The top circuit could form nanotube interconnects or gate electrodes for the bottom circuit (and vice versa), forming three dimensional integration. This overlay technique can be performed any number of times.

The steps performed in a more specific embodiment, and the resulting product, are described below.

Step 1.

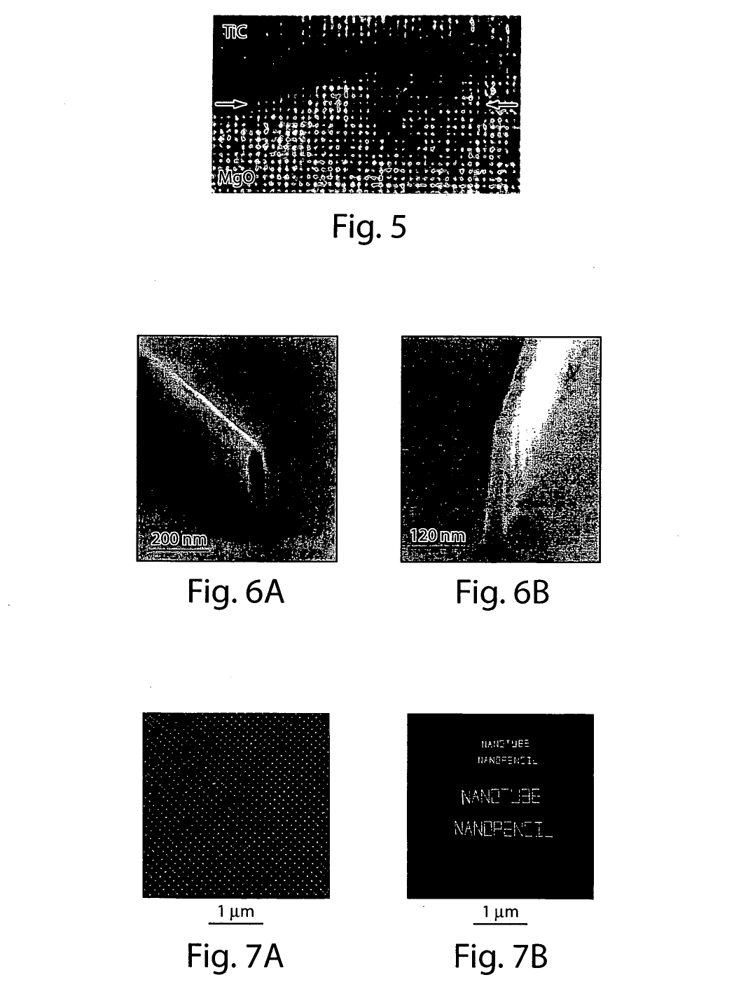

TiC(111) forms a good seed layer for graphene epitaxy and can be epitaxially grown onto e.g. MgO(111) substrates using molecular beam epitaxy (MBE), sputtering or chemical vapor deposition (CVD), see FIG. 5. Table 1 provides a list of low temperature deposited epitaxial metal carbides including, for example, SiC. These substrates can also allow TiC epitaxy.

TABLE 1

| | | | Min. temp. | Max. |
|---|---|---|---|---|
| | | | for epitaxy | Thickness |
| Carbide | Substrate | Technique | (° C.) | (Å) |
| TiC | MgO(100), | Co-evaporation | 250 | >5000 |
| | | | (co-evap.) | |
| | MgO(111), | Sputtering | 100 | |
| | 4H— | | (sputtering) | |
| | SiC(0001), | | | |
| | 6H— | | | |
| | SiC(0001) | | | |
| VC | MgO(100) | Co-evaporation | 400 | 1500 |
| | | | (co-evap.) | |
| | | Sputtering | 200 | |
| | | | (sputtering) | |
| NbC | MgO(100) | Co-evaporation | 400 | 200 |
| MoC(cubic) | MgO(100), | Co-evaporation | N.D | N.D |
| | MgO(111) | | | |
| WC(cubic) | MgO(100), | Sputtering | N.D | N.D |
| | MgO(111) | | | |
| W₂C(hex) | MgO(111) | Sputtering | N.D | N.D |
| TiC/VC* | MgO(100) | Co-evaporation, | 400 | <7000 Å |
| | | | (co-evap.) | |
| | | Sputtering | >200 | |
| | | | (sputter) | |
| TiC/NbC* | MgO(100) | Co-evaporation | 500 | N.D |
| Ti₁₋ₓVₓC | MgO(100) | Co-evaporation | 400 | N.D |
| Mo₁₋ₓNbₓC | MgO(111) | Co-evaporation | N.D | N.D |

^{a}*Denotes superlattice structures, N.D, Not determined.

Step 2.

A first step in the process involves etching the substrate, e.g., TiC, into patterns, at least some portions of the pattern or patterns having a width of about 1-20 nm, preferably, 1-5 nm. Because this process needs to be done only once (the substrate can be re-used), time consuming serial lithography techniques can be applied without compromising manufacturing cost. High resolution patterning techniques are known. For example, see K. Wilder et al., Electron beam and scanning probe lithography A comparison, J. Vac. Sci. Technol. B16(6), 10 3864 (1998). Here, feature sizes of 2 nm using e-beam, 6 nm using focused ion beam and atomic resolution using STM patterning are shown. An example of mesas etched in silicon is shown in FIG. 6. As will be appreciated from the description below, of formation of nanotubes on substrates, the ability to control lateral substrate dimensions affects dimensions in nanotubes formed on the substrates. That is, a substrate having an active surface (defined as that portion of a substrate surface upon which nanocomponents can be selectively deposited, preferably via a self-assembly technique such as chemical vapor deposition) can be used as a as a template for formation of nanotubes of different size and chirality, including continuous linear or branched nanotubes differing in size and/or chirality within different sections. The size of the active surface (the lateral dimension or dimensions of the active surface, i.e., the thinnest dimension of the components illustrated in FIGS. 6a and 6b), will directly affect the diameters of nanotubes formed thereon and therefore can affect their electronic properties.

In FIG. 6a, a 50 nm line was written using a hybrid AFM/STM scanning probe using SAL601 negative resist. Following development of the resist, the silicon was etched using HBr+O₂ plasma. In FIG. 6b, a 26 nm line was written in positive e-beam resist, PMMA, using the same scanning probe and was developed, leaving a narrow trench in the PMMA. 10 nm chrome was deposited and subsequently lifted off. After this, the silicon was etched with NF₃ based reactive ion etch.

Further enhancement of probe lithography has been obtained using a nanotube scanning probe. As shown in FIG. 7, 2 nm high, 10 nm wide silicon oxide lines have been written on a silicon wafer using a multiwall carbon nanotube.

Etched silicon wires of 5 nm high and 8 nm wide have been reproducibly obtained. Employing a single wall carbon nanotube probe tip for writing could allow lateral line sizes of 1 nm.

In many embodiments, a consistent vertical dimension is not required. The aspect ratio of the pattern can be small, since only a bilayer of graphene is to be deposited and is disconnected at the edges. Therefore, an etch depth of about 1 nm has been shown to be sufficient. The etching can be performed using, for example, standard Argon ion milling.

Advanced scanning probe techniques, including nanotube lithography, provide adequate resolution and are preferred for patterning the TiC on a master wafer.

Step 3.

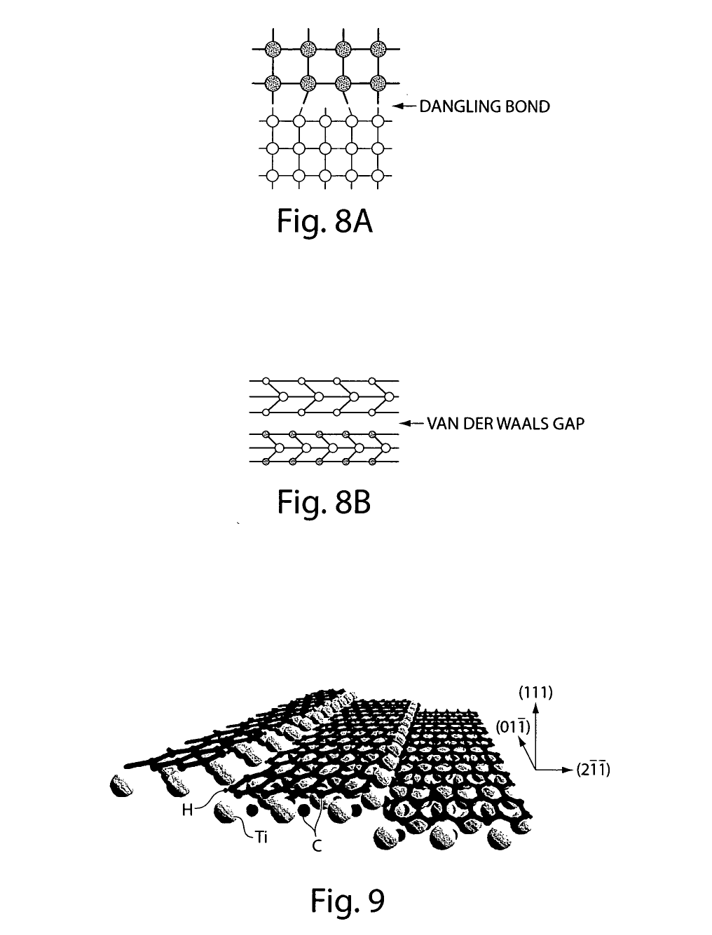

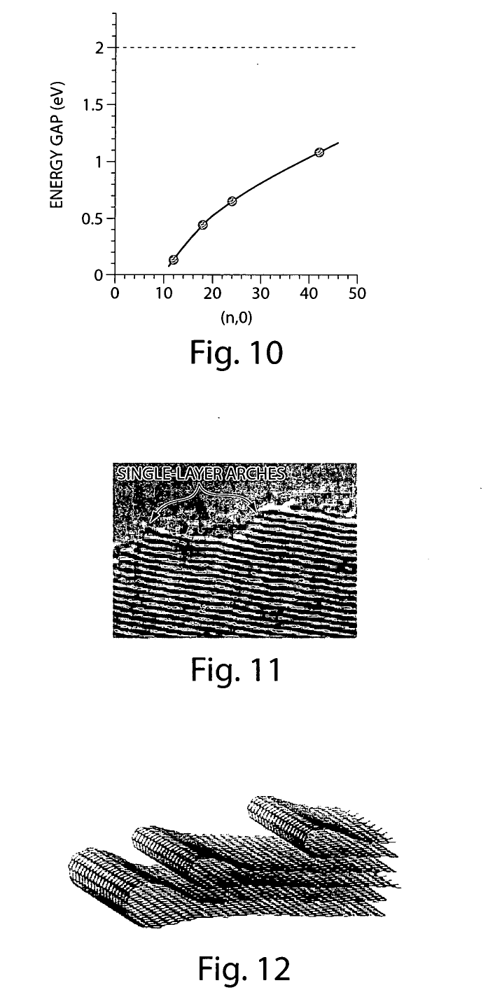

This step involves, generally, joining two non-nanotube nanocomponents to form at least one nanotube. Specifically, a first molecular layer is deposited on a substrate and a second molecular layer is deposited on the first molecular layer. The second layer may be substantially a duplicate of the first. A nanotube structure is then formed from the first and second molecular layers. The nanotube structure can be branched, formed from branched first and/or second molecular layers formed on a branched substrate. Specifically, an epitaxial graphene bilayer on top of a TiC pattern can result in nanotube formation with chirality control. The absence of molecular bonding of the graphene to the substrate may allow edge fusing and rolling of the two layers. A preferred technique for obtaining such properties is called Van-der-Waals epitaxy (VDWE). In this process, dangling bonds on a single crystal substrate are passivated, in the case of silicon, for example, using hydrogen termination. Evaporation or chemical vapor deposition can lead to xenotaxy of layered compounds such as graphite. The crystal orientation of the graphite layers are copied from the substrate (rotationally commensurate), yet the adhesion to the substrate is based on weak Van-der-Waals bonds, see FIG. 8A and B.

Monolayer and bilayer graphene can be epitaxially grown on a large variety of substrates, for example, as shown in Table 2.

TABLE 2

| | Conditions | Experimental |
|---|---|---|
| Substrates | Gases, temperatures, exposures | techniques |
| TiC(111) | C₂H₄, 1400 K, 200 L | LEED, AES, HREELS |
| TaC(100) | C₂H₄, 1400 K, 2000 L | LEED, AES, HREELS |
| TaC(111) | C₂H₄, 1100-1500 K, 200 L | LEED, AES, HREELS |
| HfC(100) | C₂H₄, 1100-1800 K, 100 000 L | LEED, AES, HREELS |
| HfC(111) | C₂H₄, 1400 K, 500 L | LEED, AES, HREELS |
| WC(0001) | Hydrocarbon, 1800-2000 K | LEED, AES, HREELS |
| LaB₆(100) | Segregation | LEED |
| Ni(100) | CO, C₂H₄ | LEED, AES, UPS |
| | CO, 600 K, 90 000 L | SEELFS |
| Ni(111) | C₂H₄ | LEED, AES |
| | Segregation | |
| Pt(111) | C₃H₆, 1150 K, 13 L | LEED, AES |
| | C₆H₆ 1100 K, 25 L | |
| | Segregation | |
| Ir(100) | C₆H₆, 1600 K, 150 L | AES, TDS |
| Ir(111) | C₆H₆, 1600 K, 150 L | AES, TDS |
| Pd(100) | Segregation | LEED, AES |
| Pd(111) | Segregation | LEED, AES |
| Re(1010) | C₆H₆, 1500-1800 K | AES, TDS |
| Ru(001) | Segregation | UPS |

TiC is one of the preferred substrates. The required amount of hydrocarbon for depositing a layer is quite small and this improves the selectivity of carbon deposition on TiC versus non-TiC substrate. In general, deposition of carbon on inert substrates such as MgO is very low, hence edge unterminated graphene can be selectively deposited on TiC patterns or stripes. Selective deposition of C₆₀ on MoS₂/GaSe has been previously shown by K. Ueno et al., in Nanostructure fabrication by selective growth of molecular crystals on layered material substrates, Appl. Phys. Lett., 70, 1104, (1997); and in A novel method to fabricate molecular quantum structures: selective growth of C₆₀ on layered material heterostructures, Jpn. J. Appl. Phys. 38, 511 (1999); and by W. Jaegermann et al., in Perspectives of the concept of Van der Waals epitaxy: growth of lattice mismatched GaSe(0001) films on Si(111), Si(110) and Si(100), Thin Solid Films 380, 276 (2000).

In contrast to growth on Ni, Fe and Co, where the hydrocarbons segregate from the transition metal particles forming nanotubes only, as mentioned above, planar growth of monolayer graphene can occur even for ultra narrow ribbons on suitable seed layers such as TiC. This is evidenced by the deposition of monolayer graphite on miscut TiC(755) substrate as shown in FIG. 9.

As shown, the terraces of the TiC(755) miscut wafers are (111) planes, with Ti terminating the top layer. As described in T. Tanaka et al., Carbon nano-ribbons and their edge phonons, Solid State Comm., 123, 33 (2002), to grow graphene sheets, the substrate can be heated to 1100K and exposed to 200L of benzene molecules. The width of the terraces was about 1.3 nm and contained 5 hexagon rings. However, in this system, depositing a second graphene layer on this system would likely lead to edge fusing from one graphene terrace to the next and would not result in nanotubes. However, on patterned TiC, edge-unterminated bilayer graphene growth could occur with likely subsequent nanotube formation. This example does show, though, that 1.3 nm wide monolayer graphene ribbons on TiC(111) would be thermodynamically stable.

Many compounds, such as carbon, boron nitride, MoS₂ and WS₂ exhibit the ability to form nanotubes. In addition to graphite, many other molecular layers can be grown in VDWE mode, for example hexagonal boron nitride (BN), tungsten disulfide (WS₂), Gallium Selenide (GaSe) and many others. See Table 3. Using the edge fusing formation described herein, such materials may be formed into new types of nanotubes. Theoretical calculations show that GaSe nanotubes are stable and that the GaSe bandgap increases with diameter, being virtually metallic at small diameters and semiconducting at larger diameters. Table 3 provides several materials have been grown using VDWE. T stands for transition metal such as Mo and X for a chalcogen such as S or Se.

TABLE 3

| Material group | Materials grown with Vd. WE |
|---|---|
| Quasi-1D | Se/Te |
| | Te/Se/Te |
| Quasi-2D | TX₂/TX₂ |
| | TX₂/SnS₂ |
| | TX₂/mica |
| | GaSe/TX₂ |
| Quasi-2D | TX₂/S—GaAs (1 1 1) |
| on 3D | GaSe/Se—GaAs (1 1 1) |
| | GaSe/H—Si(1 1 1) |
| | TX₂/CaF₂ (1 1 1) |
| Organic | Phthalocyanines/MoS₂ |
| | Phthalocyanines/H—Si (1 1 1) |
| | Phthalocyanines/Se—GaAs (1 1 1) |
| | C₆₀/MoS₂, C₆₀/GaSe |
| | Coronene/TX₂ |

During van der Waals epitaxy, the layers can optionally be doped with impurities to modify the electronic properties of the tubes. TiC(111) and MgO(111) and graphene merely serve as examples and preferred embodiment, however, combinations of materials, such as those mentioned in Tables 1, 2 and 3 are included, as well as other suitable configurations.

In an alternative embodiment, the graphite bilayer is not grown selectively via chemical vapor deposition, but evaporated onto the TiC mesas, and due to the vertical sidewalls of the mesa and directionality of the molecular beam, the deposition on the walls is negligible. Hence, the bilayer deposited on the mesa top will be substantially edge unterminated. Molecular beam epitaxy of organic monolayers is known and is reviewed in K. Ueno et al., in Nanostructure fabrication by selective growth of molecular crystals on layered material substrates, Appl. Phys. Lett., 70, 1104, (1997); and in A novel method to fabricate molecular quantum structures: selective growth of C₆₀ on layered material heterostructures, Jpn. J. Appl. Phys. 38, 511 (1999); and by W. Jaegermann et al., Perspectives of the concept of Van der Waals epitaxy: growth of lattice mismatched GaSe(000) films on Si(111), Si(110) and Si(100), Thin Solid Films 380, 276 (2000).

Step 4.

After the deposition of a second graphene layer, edge dangling bonds of the graphene ribbons are available for bonding. The edge state of the nano-ribbons can be compared to a single side edge state as it occurs naturally on the sides of graphite crystals. Here, theoretical and experimental evidence for edge state bonding and folding into arches is provided in S. V. Rotkin and Y. Gogotsi, Analysis of non-planar graphitic structures: from arched edge planes of graphite crystals to nanotubes, Mat Res Innovat 5, 191 (2002). See FIGS. 11 and 12.

A sleeve at the edge of graphite is predicted to have an optimum diameter of 1.5-2 nm. The diameter depends neither on the edge structure nor on the defects or contamination. It is believed to be solely defined by the van der Waals cohesion and the elastic energy of the rolled graphene layers.

In the case of patterned bilayer graphite nanoribbons defined herein, edge folding on both sides will naturally form nanotubes, with chirality determined by the angle of the TiC(111) pattern with the horizontal axis. The tube diameter d will be d=2w/Pi, where w is the graphene ribbon width.

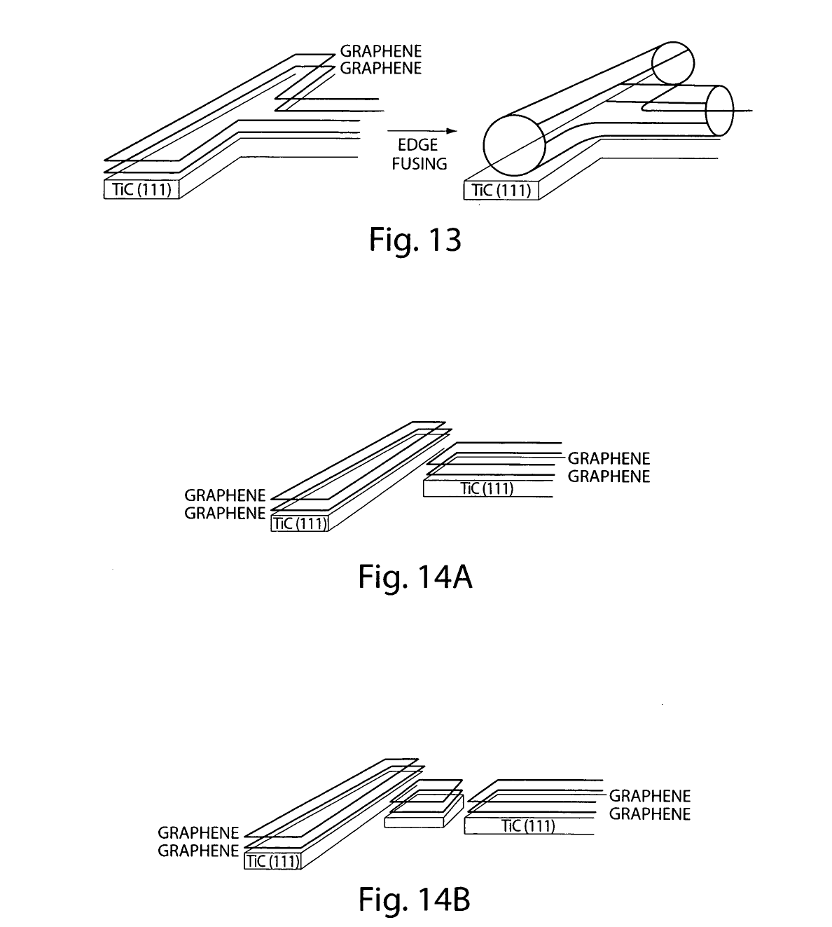

In addition to nanotube formation from the graphene ribbons, more complicated structures can be formed, for example, a T junction in the patterned TiC, can lead to a T nanotube junction, as shown in FIG. 13, where a first molecular layer is deposited on a branched substrate and a second molecular layer is deposited on the first molecular layer. The result is formation of a branched nanotube structure from the first and second molecular layers. As can be seen, the branched pattern of the substrate directs the shape of the nanotube structure.

The conducting properties of the branched nanotube structure can be controlled, at least in part, by the angles of the arms in the T or Y junctions. Experimentally, a Y junction has been formed using electron microscope irradiation of a crossed nanotube. According to theoretical calculations, when semiconducting nanotubes are connected to metallic leads, non-transmitting states are induced at the nanotube-metal interface, leading to asymmetric transmission curves and potentially rectifying behavior of the nanodevice. As shown, the branched nanotube formed according to the technique of FIG. 13 has essentially uniform diameters, although the branched substrate pattern can include portions of non-uniform width and can therefore result in a nanotube or nanotubes, or nanotube structure with different nanotube portions having different diameters.

Clearly, novel functionality is not limited to T and Y-junctions. For example, double side gated junctions can form a single device AND or OR gate and a large variety of electronic devices can be formed using this bilayer graphene edge fusing. Two examples are shown in FIG. 14.

The lateral floating gate example in FIG. 14B can be advantageous, because nanotubes are known for their excellent field emission properties.

One aspect of the invention involves depositing nanocomponents on substrates that are patterned so as to impart, in a nanotube or nanotubes formed from nanocomponents made in this way, different electronic properties in different sections of the nanotube and/or in different nanotubes. For example, the invention can involve depositing non-nanotube nanocomponents on a substrate, where molecular orientation in the nanocomponent is affected by a feature of the substrate (such as the crystal lattice structure of the active surface of the substrate) upon which the nanocomponent is deposited. E.g., a graphene sheet deposited from chemical vapor onto certain substrates exposing specific crystal lattice structures will have a molecular orientation defined by the lattice structure and can still be transferred from the lattice structure. Where a substrate is defined by an exposed surface having a particular crystal lattice structure that can control graphene orientation, the substrate can be etched so as to provide active surfaces for graphene deposition having any orientation relative to the crystal lattice structure. Deposition of nanocomponents defining multiple molecular layers of graphene on active substrate surface sections having longitudinal axes orientated differently relative to the crystal lattice structure active surface, and subsequent nanotube formation, can result in nanotubes of different chirality and therefore different conductivity. Different widths of substrate active surface units can result in different diameters of nanotubes, thus both chirality and diameter of nanotubes (or either, independently), can be controlled and will affect the conductivity of the resulting nanotube, as will be appreciated with reference to FIGS. 1 and 2 and related discussion. A variety of nanotubes of different conductivity can be fabricated in this way, and assembled together (optionally using Van der Waals epitaxy as described herein) to form a variety of useful objects such as nanoelectronic components involving circuits, etc. Those of ordinary skill in the art can form useful devices from nanotubes having different properties as described and enabled herein, with reference to a variety of literature sources (e.g., International Patent Publication nos. WO 01/03208, published Jan. 11, 2001, and WO 03/005450, published Jan. 16, 2003, each by Lieber, et al., each incorporated herein by reference).

A substrate defining an exposed surface having a particular crystal lattice structure that can control molecular orientation of graphene deposited thereon can be etched so as to define a pattern of connected (or un-connected) longitudinal sections orientated longitudinally, different from each other, therefore orientated differently with respect to the crystal lattice of the substrate. Where graphene molecular layers are deposited on such a patterned substrate, and a nanotube array is formed from these deposited nanocomponents (see, for example, FIG. 13), the array will include different nanotube sections having different conductivities; the conductivity of each nanotube section will be determined, e.g., by the chirality of the combination of the graphene sheet components defining that section which will, in turn, be defined by the crystal lattice orientation of the section of the patterned active substrate surface onto which those graphene sheets have been deposited. Stated another way, the resultant nanotube pattern, which can define an electrical circuit, will include at least a first portion having a first longitudinal orientation with a first conductance and second portion, molecularly joined to the first portion, having a second longitudinal orientation different from the first orientation and a second conductance different from the first conductance. The conductance of a portion can be defined, at least in part, by its orientation on a substrate. More generally, the second portion can have a different chirality and/or diameter than the first portion, dictated by the width (or varying diameter) of the portion of the patterned substrate upon which each of the first and second portions was formed, and/or the first portion will be formed on a portion of the substrate having a different molecular orientation than the orientation upon which the second portion is formed, where orientation is defined relative to the longitudinal axis of each portion of the nanotube.

Step 5.

The nanotubes formed in step 4 are weakly bonded to the TiC(111) substrate film by van de Waals bonds. It is well known from wafer bonding technology, that when two silicon wafers are brought into intimate contact, adhesion occurs between the wafers based on van der Waals bonds between adsorbed water and OH groups. This wafer pair can be easily separated without damaging either surface, by inserting a razor blade between them, demonstrating that van der Waals bonds can be broken to non-destructively separate even more strongly bonded entities. Similarly, weakly van der Waals bonded nanotubes can be removed from their supporting substrate by, for example, using a sticky tape, as has been shown in M. D. Frogley and H. D. Wagner, Mechanical alignment of quasi one dimensional particles stamping nanotubes, J. Nanoscience and Nanotechnology, 2,517 (2002). Here random nanotubes dispensed on a rubber substrate were transferred to a sticky tape simply by peeling it off the rubber. The distribution was shown to be similar to that on the substrate.

There are also more advanced techniques known in the field of soft lithography, a collective name for a set of lithographic techniques—replica molding, microcontact printing, micro molding in capillaries, microtransfer molding, solvent assisted micromolding and near field conformal photolithography using an elastomeric phase shifting mask. Microcontact printing is similar to the nanotube circuit stamping described herein, however has mainly been demonstrated for self assembled monolayers. Platinum wires as narrow as 8 nm have been transferred using a technique called superlattice nanowire pattern transfer. Here, a cleaved GaAs/AlGaAs epitaxial wafer is etched and the pattern is deposited on the cleaved side is transferred by etching a sacrificial GaAs oxide. The latter technique is not suitable for arbitrary pattern transfer as only parallel wires can be stamped. It demonstrates, however, that narrow lines can be easily transferred, even over large areas.

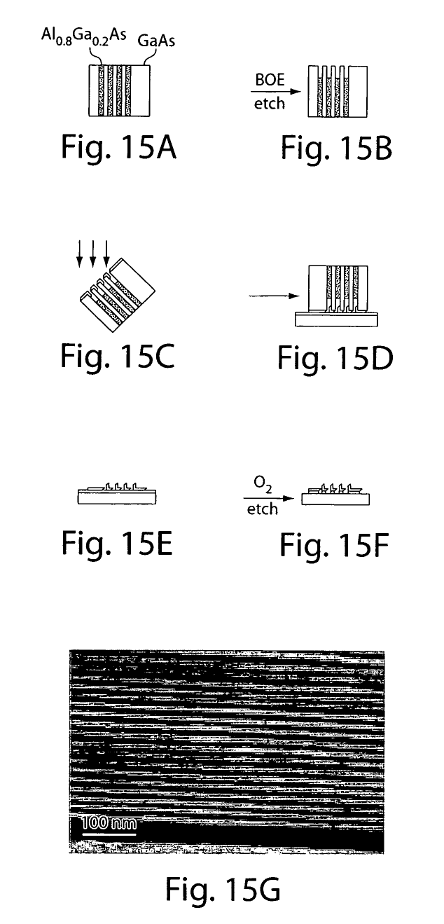

Films deposited by van der Waals epitaxy are suited for nano imprinting, more so than for example the Pt wires of FIG. 15, which require an etching step of sacrificial GaAs oxide to release the Pt. Because of the poor adhesion of van der Waals epitaxial films and/or their edge fused nanotubes and circuits to their substrate, this technique does not require any etching, and could be called van der Waals epitaxy imprinting.

Step 6.

Using van der Waals epitaxy imprinting, a second nanotube circuit could be stamped on top of the first, where the second circuit could for example form gates and or interconnects of the first circuit and vice versa. In addition, the second circuit could be stamped after deposition of an insulating film. Carbon nanotube transistors and single device And and OR gates have been demonstrated using metal gates and atomic layer deposited insulators, however, top gating using stamped nanotube circuits allows much higher integration density.

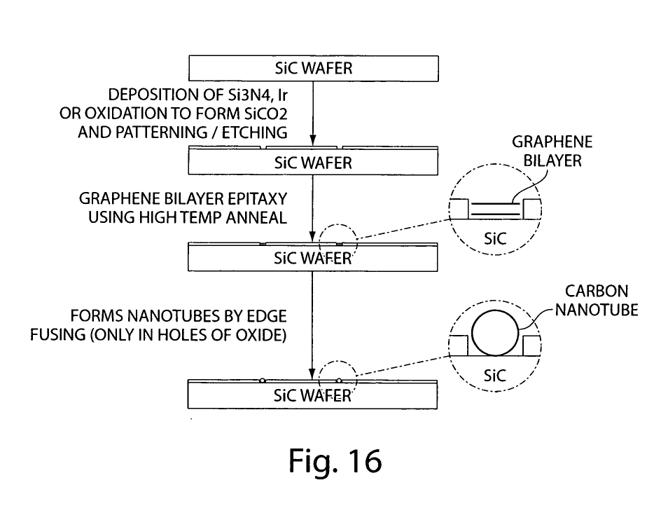

In another set of embodiments, a graphene layer, or layers, can be formed by converting a multi-component layer to a graphene monolayer. For example, a layer containing carbon can be subjected to conditions that allow one or more non-carbon components of the layer to evaporate, forming a graphene layer in place. In one particular embodiment, silicon carbon can be annealed, resulting in two monolayers of graphite. A silicon carbide wafer having a patterned material (such as silicon nitride or iridium, which are inert and don't typically form carbides) on top can be used by forming stripes of double layer graphene by annealing at about 1300° C. in vacuum. When the silicon is evaporated from the silicon carbide wafer, carbon remains after the silicon is evaporated. A single molecular layer of carbon may remain. Additional layers can be formed by further evaporating the silicon carbide wafer. As a second graphene layer is formed, edge fusion of two layers can result in a nanotube. Under some conditions, nanotube formation may happen spontaneously upon production of the second layer. A schematic diagram illustrating one such process is provided in FIG. 16.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B”, when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of”, when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one act, the order of the acts of the method is not necessarily limited to the order in which the acts of the method are recited.

In the claims, as well as in the specification above, all transitional phrases such as comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A method comprising:
providing at least first and second separate, non-nanotube nanocomponents; and
joining the at least first and second nanocomponents to form a nanotube.

2. A method comprising:
forming a first molecular layer and a second molecular layer, both on a branched pattern on a substrate; and
joining the first and second layers to form a branched nanotube structure wherein the branched pattern directs the shape of the nanotube structure.

3. The method of claim 2, comprising forming the second molecular layer on the first molecular layer.

4. The method of claim 2, comprising forming the first molecular layer on the branched pattern on the substrate, then forming the second molecular layer on the first molecular layer.

5. The method of claim 2 wherein at least one molecular layer comprises carbon.

6. The method of claim 3 wherein at least one molecular layer comprises graphene.

7. The method of claim 2 wherein at least one molecular layer consists essentially of carbon.

8. The method of claim 2 wherein the branched pattern includes portions of non-uniform width.

9. The method of claim 2 wherein the branched nanotube structure comprises portions exhibiting different chirality.

10. The method of claim 2 wherein the branched nanotube structure comprises portions exhibiting different electrical characteristics.

11. The method of claim 2 wherein the substrate comprises titanium carbide.

12. The method of claim 11 wherein the substrate comprises titanium carbide on a magnesium oxide surface.

13. The method of claim 2 wherein the forming step is repeated on the substrate.

14. The method of claim 2 further comprising removing the branched nanotube from the substrate.

15. The method of claim 2 wherein the first and second layer are deposited on the substrate.

16. A method of forming a branched nanotube structure comprising:
providing a first substantially planar branched molecular structure; and
annealing the molecular structure to a second substantially planar branched molecular structure to produce the branched nanotube structure.

17. The method of claim 16 wherein the first molecular structure comprises carbon.

18. The method of claim 16 wherein the first molecular structure comprises graphite.

19. The method of claim 18 wherein the graphite comprises graphene.

20. The method of claim 16 wherein the first molecular structure consists essentially of carbon.

21. The method of claim 16 wherein the first molecular structure comprises portions of non-uniform width.

22. The method of claim 16 wherein the branched nanotube structure comprises portions exhibiting different chirality.

23. The method of claim 16 wherein the branched nanotube structure comprises portions exhibiting different electrical characteristics.

24. The method of claim 16 wherein the first and second branched molecular structures comprise common molecular structure.

25. The method of claim 22 further comprising forming a molecular layer on a crystal lattice and forming the multi-chiral nanotube from the molecular layer.

26. The method of claim 25 wherein the molecular layer is deposited on the crystal lattice.

27. A nanotube comprising:
a first substantially cylindrical portion exhibiting a first molecular structure and a first electrical characteristic; and
a second substantially cylindrical portion exhibiting the first molecular structure and a second electrical characteristic.,
wherein each of the first and second portions comprises at least two carbon rings.

28. The nanotube of claim 27 wherein the electrical characteristic is conductivity.

29. The nanotube of claim 27 wherein the molecular structure comprises carbon.

30. The nanotube of claim 29 wherein the molecular structure comprises hexagonal carbon.

31. The nahotube of claim 27 wherein each of the first and second portions have a longitudinal length greater than the radius of the portion.

32. A method of making a nanotube comprising:
forming a first molecular layer and a second molecular layer, each in substantially the same shape; and
molecularly annealing the first layer to the second layer to produce the nanotube.

33. The method of claim 32, comprising forming the first molecular layer in a first shape, then forming the second molecular layer in substantially the same shape.

34. The method of claim 32 further comprising separating the nanotube from the substrate.

35. The method of claim 33 further comprising making a second nanotube on the substrate.

36. A method of making a nanotube comprising:
forming a molecular layer having at least first and second elongated portions, the first portion having a first orientation on a crystal lattice substrate and the second portion having a second orientation on the crystal lattice substrate wherein the first orientation is different from the second orientation; and
forming a nanotube from the molecular layer wherein the nanotube includes a first portion having a first chirality and a second portion having a second chirality.

37. The method of claim 36 wherein the first portion of the nanotube is metallic and the second portion of the nanotube is semi-conductive.

38. A method comprising:
imprinting a crystal lattice pattern onto a substrate;
epitaxially forming a molecular layer on the pattern; and
removing the molecular layer from the pattern.

39. The method of claim 38 wherein the molecular layer comprises carbon.

40. The method of claim 38 wherein the molecular layer comprises GaAs.

41. The method of claim 38 wherein the pattern comprises an electrical circuit.

42. The method of claim 41 wherein electrical characteristics of a portion of the circuit is determined by the alignment of the portion in relation to a planar axis of the substrate.

43. The method of claim 41 wherein the circuit is formed without etching.

44. A circuit comprising:
a pattern of nanotubes comprising a first portion having a first longitudinal orientation and a first conductance and a second portion molecularly joined to the first portion and having a second longitudinal orientation different from the first orientation and a second conductance different from the first conductance.

45. A method of making a circuit comprising:
forming a pattern on a substrate;
producing a crystalline molecular layer on the pattern without producing a substantial amount of molecular layer on non-patterned portions of the substrate; and
forming a circuit from the molecular layer wherein the conductivity of a portion of the circuit is determined by a horizontal dimension of the portion.

46. The method of claim 45 wherein the crystalline molecular layer is deposited on the pattern.

47. A method of making a circuit comprising:
forming a pattern on a substrate;
depositing a crystalline molecular layer on the pattern without depositing a substantial amount of molecular layer on non-patterned portions of the substrate; and
forming a circuit from the molecular layer wherein the conductivity of a portion of the circuit is determined by an orientation of the portion in relation to the crystal lattice structure of the substrate.

48. The method of claim 47 further comprising forming a second identical circuit on the patterned substrate.

49. The method of claim 47 wherein the molecular layer comprises graphene.

50. The method of claim 47 wherein the molecular layer comprises a compound selected from gallium, selenium, antimony and sulfur.
